(19) United States
(12) Patent Application Publication
(10) Pub. No.: US 2016/0105170 A1
(43) Pub. Date: Apr. 14, 2016

(54) RESET SIGNAL GENERATOR AND INTEGRATED CIRCUIT HAVING THE SAME

(71) Applicant: Samsung Electro-Mechanics Co., Ltd., Suwon-Si (KR)

(72) Inventors: Joon Hyung LIM, Suwon-Si (KR); Ji Buem CHUN, Suwon-Si (KR); Myeung Su KIM, Suwon-Si (KR)

(73) Assignee: SAMSUNG ELECTRO-MECHANICS CO., LTD., Suwon-Si (KR)

(21) Appl. No.: 14/678,378

(22) Filed: Apr. 3, 2015

(30) Foreign Application Priority Data
Oct. 14, 2014 (KR) 10-2014-0138543

(51) Int. Cl. H03K 17/22

(52) U.S. Cl. CPC H03K 17/223

(57) ABSTRACT

A reset signal generator may include a voltage divider dividing a voltage level of a driving voltage, a reference voltage generator generating a reference voltage by performing a switching operation on the driving voltage depending on a voltage level of the divided driving voltage from the voltage divider, and a comparator comparing the voltage level of the divided driving voltage and the reference voltage to output a reset signal depending on the comparison result. The integrated circuit includes the reset signal generator and a controller resetting a control operation depending on the reset signal.

### CROSS-REFERENCE TO RELATED APPLICATION

This application claims priority to, and the benefit of, Korean Patent Application No. 10-2014-0138543 filed on Oct. 14, 2014, with the Korean Intellectual Property Office, the disclosure of which is incorporated herein by reference.

### BACKGROUND

The present disclosure relates to a reset signal generator generating a reset signal, and an integrated circuit having the same.

An operating voltage of an integrated circuit is generally defined by a specification.

However, in order to guarantee stable operations of the integrated circuit, the integrated circuit is designed so that it may be operated within a range wider than that of the operating voltage defined by the specification.

However, since a system is typically configured by a combination of integrated circuits, it may be difficult to satisfy specifications of operating voltage ranges of all integrated circuits mounted in the system. In addition, if power fluctuates due to an unstable power supplying apparatus of the system, a situation in which any integrated circuit may be operated and any integrated circuit may not be operated may occur.

In order to prevent the above-mentioned problem, a circuit that generates a reset signal for stopping the operation of the system when a source voltage is not within a predetermined range is required.

The above-mentioned reset signal generator compares a reference voltage with the source voltage and uses a bandgap circuit in order to provide an accurate reference voltage as described in the following Related Art Document.

However, the above-mentioned bandgap circuit generates the reference voltage by using the source voltage. When a level of the source voltage is suddenly changed, a voltage level of the reference voltage fluctuates and a glitch signal occurs depending on the fluctuation of the voltage level of the reference voltage.

[Related Art Document]

(Patent Document 1) Korean Patent Laid-Open Publication No. 10-2011-0037384

### SUMMARY

An aspect of the present disclosure may provide a reset signal generator in which a glitch signal is not generated despite a sudden change in a level of a source voltage, and an integrated circuit having the same.

According to an aspect of the present disclosure, a reset signal generator may include: a voltage divider dividing a voltage level of a driving voltage; a reference voltage generator generating a reference voltage by performing a switching operation on the driving voltage depending on a voltage level of the divided driving voltage from the voltage divider; and a comparator comparing the voltage level of the divided driving voltage and the reference voltage to output a reset signal depending on the comparison result. According to another aspect of the present disclosure, an integrated circuit may include: the reset signal generator described above and a controller resetting a control operation depending on the reset signal.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram of an integrated circuit according to an exemplary embodiment in the present disclosure;

FIG. 2 is a graph showing a general driving voltage and a reset signal;

FIG. 3 is a graph showing a glitch phenomenon of a general reset signal;

FIG. 4 is a schematic circuit diagram of a reset signal generator according to an exemplary embodiment in the present disclosure;

FIG. 5 is a reference voltage graph of the reset signal generator according to an exemplary embodiment in the present disclosure;

FIG. 6 is a reset signal graph of the reset signal generator according to an exemplary embodiment of the present disclosure; and

FIG. 7 is a graph between the driving voltage and the reset signal of the reset signal generator according to an exemplary embodiment in the present disclosure.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

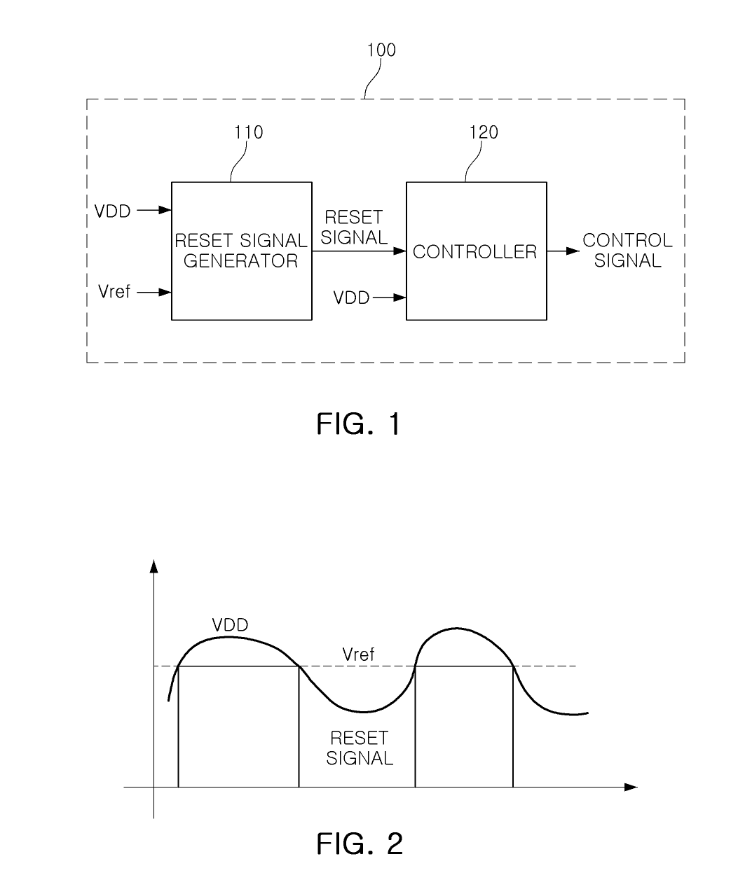

FIG. 1 is a schematic block diagram of an integrated circuit according to an exemplary embodiment in the present disclosure.

Referring to FIG. 1, an integrated circuit 100 according to an exemplary embodiment in the present disclosure may include a reset signal generator 110 and a controller 120.

The reset signal generator 110 may compare a voltage level of a driving voltage VDD and a reference voltage Vref and may generate a reset signal depending on the comparison result.

The reset signal generator 110 may generate the reset signal in the case in which the voltage level of the driving voltage VDD is lower than a voltage level of the reference voltage Vref.

The reset signal may be transferred to the controller 120.

The reference voltage Vref, which is a reference providing the above-mentioned reset signal, may be varied depending on the voltage level of the driving voltage VDD.

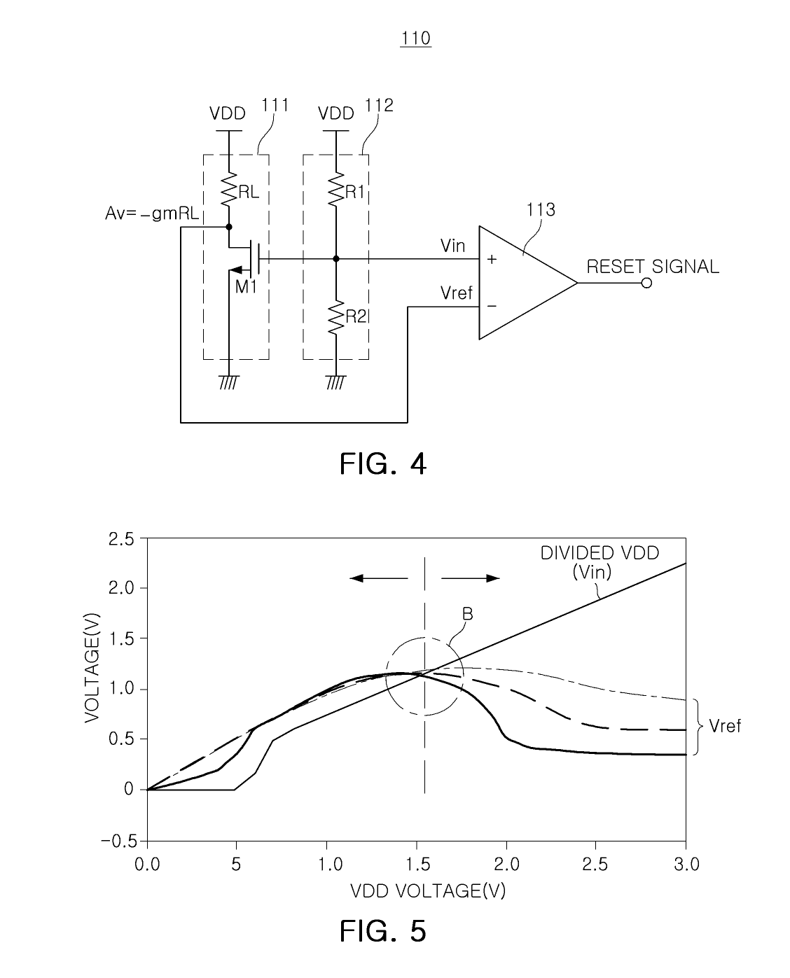

The above-mentioned operation will be described in more detail with reference to FIGS. 4 through 7.

Meanwhile, FIG. 2 is a graph showing a general driving voltage and a reset signal.

As shown in FIG. 2, in general, the reset signal generator may compare the voltage level of the driving voltage VDD and the reference voltage Vref and may generate the reset signal depending on the comparison result.

That is, the reset signal generator 110 may compare the voltage level of the driving voltage VDD and the reference voltage Vref and may generate the reset signal of a low level in the case in which the voltage level of the driving voltage VDD is lower than the reference voltage Vref.

The controller 120 may be supplied with the driving voltage VDD and provide a control signal controlling an operation of the integrated circuit 100.

Since the controller 120 is likely to malfunction in the case in which the voltage level of the driving voltage VDD is a predetermined voltage level or less, it may receive a reset signal from the reset signal generator 110 so as to reset a control operation, thereby preventing the malfunction of the integrated circuit.

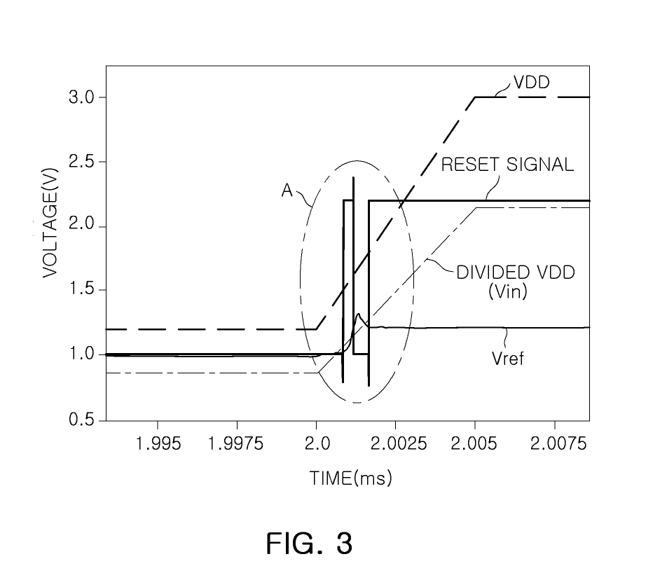

FIG. 3 is a graph showing a glitch phenomenon of a general reset signal.

Referring to FIG. 3, in general, in the case in which the voltage level of the driving voltage VDD is sharply varied, a voltage level of a divided driving voltage is also sharply varied. Accordingly, it may be seen that the reference voltage instantaneously rises and drops, which causes a glitch phenomenon in the reset signal as indicated by reference numeral ‘A’.

FIG. 4 is a schematic circuit diagram of a reset signal generator according to an exemplary embodiment of the present disclosure.

Referring to FIG. 4, the reset signal generator 110 according to an exemplary embodiment of the present disclosure may include a reference voltage generator 111, a voltage divider 112, and a comparator 113.

The reference voltage generator 111 may include a transistor M1 and a resistor RL.

A drain of the transistor M1 may be connected to a driving voltage terminal supplying the driving voltage VDD, a source thereof may be connected to a ground, and a gate thereof may be connected to the voltage divider 112.

The resistor RL may be connected between the driving voltage terminal and the drain of the transistor M1. That is, the driving voltage VDD may be transferred to the drain of the transistor M1 through the resistor RL.

The voltage divider 112 may include a first voltage dividing resistor R1 and a second voltage dividing resistor R2.

The first voltage dividing resistor R1 and the second voltage dividing resistor R2 may be connected to each other in series between the driving voltage terminal and the ground.

A connection point between the first voltage dividing resistor R1 and the second voltage dividing resistor R2 may be connected to the gate of the transistor M1.

The driving voltage VDD may be divided depending on a resistance ratio of the first voltage dividing resistor R1 and the second voltage dividing resistor R2, and a voltage level of the divided driving voltage Vin may be input to a plus terminal (+) of the comparator 113.

The reference voltage Vref from the reference voltage generator 111 may be input to a minus terminal (−) of the comparator 113.

The comparator 113 may compare the divided driving voltage Vin and the reference voltage Vref and may generate the reset signal in the case in which the voltage level of the divided driving voltage Vin is lower than the voltage level of the reference voltage Vref.

Accordingly, in the case in which the voltage level of the driving voltage VDD is a predetermined voltage level or less, the comparator 113 may provide a reset signal resetting the controller 120 in order to protect an operation of the integrated circuit 100.

Since the divided driving voltage Vin may be input to the gate of the transistor M1 of the reference voltage generator 111, the transistor M1 may be turned on or off depending on the voltage level of the divided driving voltage Vin and may amplify the driving voltage VDD.

Consequently, the reference voltage Vref may be determined by the following Equation.

Av=ΔVref/ΔVin=−gm*RL

Vref=−Vin*RL*gm (Equation)

wherein, Av is a voltage gain of the comparator, Vin is the voltage level of the divided driving voltage Vin, RL is a resistance value of the resistor RL, and gm is transconductance of the transistor M1.

FIG. 5 is a reference voltage graph of the reset signal generator according to an exemplary embodiment of the present disclosure.

Referring to FIG. 5, when the driving voltage VDD is varied from 0V to 3V, the divided driving voltage Vin has a voltage level lower than the driving voltage VDD, and the divided driving voltage Vin is input to the comparator 131, so that the reference voltage may be generated according to the above-mentioned Equation.

However, based on a threshold voltage value (see reference numeral ‘B’) at which a graph of the divided driving voltage Vin and a graph of the reference voltage Vref intersect with each other, since the voltage level of the reference voltage Vref is higher than the voltage level of the divided driving voltage Vin at the threshold voltage value or less and the voltage level of the reference voltage Vref is lower than the voltage level of the divided driving voltage Vin at the threshold voltage value or more, an accurate reset signal may be provided even in the case in which the reference voltage Vref is compared to the divided driving voltage Vin.

In addition, since a phenomenon in which the voltage level of the reference voltage Vref and the voltage level of the divided driving voltage Vin are reversed does not occur at the threshold voltage value or more and the threshold voltage value or less even in the case in which the driving voltage VDD is sharply changed, an occurrence of a glitch phenomenon in the reset signal may be prevented.

Although a plurality of reference voltages Vref are shown in the shown graph, this shows that an occurrence of a glitch phenomenon in the reset signal may be prevented since the phenomenon in which the voltage level of the reference voltage Vref and the voltage level of the divided driving voltage Vin are reversed does not occur at the threshold voltage value or more and the threshold voltage value or less as described above even in the case in which the reference voltage Vref is slightly changed depending on IC process deviation and temperature.

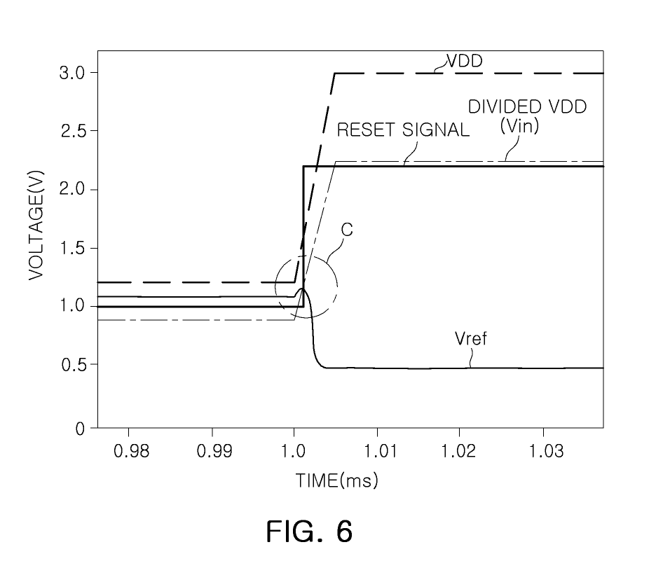

FIG. 6 is a reset signal graph of the reset signal generator according to an exemplary embodiment of the present disclosure.

Referring to FIG. 6, the reference voltage Vref is changed depending on the driving voltage VDD. However, based on a threshold voltage value (see reference numeral ‘C’) at which the voltage level of the reference voltage Vref and the voltage level of the divided driving voltage Vin are matched to each other, since a phenomenon in which the voltage level of the reference voltage Vref is higher than the voltage level of the divided driving voltage Vin at the threshold voltage value or less and the voltage level of the reference voltage Vref is lower than the voltage level of the divided driving voltage Vin at the threshold voltage value or more is maintained, the glitch phenomenon may not occur in an output signal of the comparator 113.

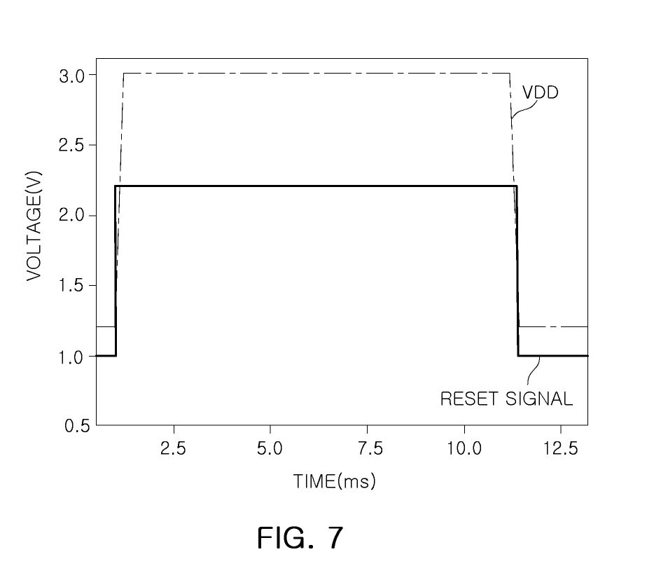

FIG. 7 is a graph between the driving voltage and the reset signal of the reset signal generator according to an exemplary embodiment of the present disclosure.

Referring to FIG. 7, since a signal level of the output signal of the comparator is also increased in the case in which the voltage level of the driving voltage VDD is sharply increased and the signal level of the output signal of the comparator is also decreased in the case in which the voltage level of the driving voltage VDD is sharply decreased, it may be seen that the reset signal is accurately generated even in the case in which the voltage level of the driving voltage VDD is sharply decreased.

As described above, according to the present disclosure, the accurate reset signal may be provided by suppressing the glitch phenomenon even in the case in which the driving voltage is sharply changed, and consequently, the operation of the integrated circuit may be stably protected even in the case in which the driving voltage is sharply changed.

As set forth above, according to exemplary embodiments of the present disclosure, the reset signal generator may provide a stable reset signal.

In addition, the integrated circuit may be stably operated.

While exemplary embodiments have been shown and described above, it will be apparent to those skilled in the art that modifications and variations could be made without departing from the scope of the present invention as defined by the appended claims.

What is claimed is:

1. A reset signal generator comprising:
a voltage divider dividing a voltage level of a driving voltage;
a reference voltage generator generating a reference voltage by amplifying the driving voltage depending on a voltage level of the divided driving voltage from the voltage divider; and
a comparator comparing the voltage level of the divided driving voltage and the reference voltage to output a reset signal depending on the comparison result.

2. The reset signal generator of claim 1, wherein the reference voltage generator varies a voltage level of the reference voltage depending on a voltage level variation of the divided driving voltage.

3. The reset signal generator of claim 1, wherein the reference voltage generator includes:
a transistor having a gate to which the divided driving voltage from the voltage divider is input, a source connected to a ground, and a drain to which the driving voltage is input, and having transconductance gm; and
a resistor connected between a driving voltage terminal transferring the driving voltage and the drain of the transistor.

4. The reset signal generator of claim 3, wherein the reference voltage generator generates the reference voltage depending on a product of the voltage level of the driving voltage, the voltage level of the divided driving voltage, the transconductance of the transistor, and a resistance value of the resistor.

5. The reset signal generator of claim 1, wherein the voltage divider includes a first voltage dividing resistor and a second voltage dividing resistor connected to each other in series between a driving voltage terminal transferring the driving voltage and a ground.

6. The reset signal generator of claim 1, wherein the comparator generates the reset signal when the voltage level of the divided driving voltage is lower than a level of the reference voltage.

7. An integrated circuit comprising:
a reset signal generator generating a reference voltage by amplifying a driving voltage depending on a voltage level of a divided driving voltage obtained by dividing the voltage level of the driving voltage, and comparing the voltage level of the divided driving voltage and the reference voltage to output a reset signal depending on the comparison result; and
a controller resetting a control operation depending on the reset signal.

8. The integrated circuit of claim 7, wherein the reset signal generator includes:
a voltage divider dividing the voltage level of the driving voltage;
a reference voltage generator generating the reference voltage by performing a switching operation on the driving voltage depending on the voltage level of the divided driving voltage provided by the voltage divider; and
a comparator comparing the voltage level of the divided driving voltage and the reference voltage to output the reset signal depending on the comparison result.

9. The integrated circuit of claim 8, wherein the reference voltage generator varies a voltage level of the reference voltage depending on a voltage level variation of the divided driving voltage.

10. The integrated circuit of claim 9, wherein the reference voltage generator includes:
a transistor having a gate to which the divided driving voltage from the voltage divider is input, a source connected to a ground, and a drain to which the driving voltage is input, and having transconductance gm; and
a resistor connected between a driving voltage terminal transferring the driving voltage and the drain of the transistor.

11. The integrated circuit of claim 10, wherein the reference voltage generator generates the reference voltage depending on a product of the voltage level of the driving voltage, the voltage level of the divided driving voltage, the transconductance of the transistor, and a resistance value of the resistor.

12. The integrated circuit of claim 7, wherein the voltage divider includes a first voltage dividing resistor and a second voltage dividing resistor connected to each other in series between a driving voltage terminal transferring the driving voltage and a ground.

13. The integrated circuit of claim 7, wherein the comparator generates the reset signal when the voltage level of the divided driving voltage is lower than a level of the reference voltage.
